(19) United States
(12) Patent Application Publication
(10) Pub. No.: US 2019/0369483 A1
(43) Pub. Date: Dec. 5, 2019

(54) SUBSTRATE WITH CONDUCTIVE FILM, SUBSTRATE WITH MULTILAYER REFLECTIVE FILM, REFLECTIVE MASK BLANK, REFLECTIVE MASK AND METHOD FOR MANUFACTURING SEMICONDUCTOR DEVICE

(71) Applicant: HOYA CORPORATION, Tokyo (JP)

(72) Inventors: Yohei IKEBE, Tokyo (JP); Tsutomu SHOKI, Tokyo (JP)

(73) Assignee: HOYA CORPORATION, Tokyo (JP)

(21) Appl. No.: 16/477,801

(22) PCT Filed: Jan. 16, 2018
(86) PCT No.: PCT/JP2018/000961

§ 371 Date: Jul. 12, 2019

(30) Foreign Application Priority Data
Jan. 17, 2017 (JP) 2017-005773
Mar. 2, 2017 (JP) 2017-039100

(51) Int. Cl. G03F 1/24; G03F 1/26; G03F 7/20

(52) U.S. Cl. CPC G03F 1/24; G03F 7/20; G03F 1/26

(57) ABSTRACT

Provided is a substrate with conductive film for fabricating a reflective mask capable of correcting misalignment of the reflective mask from the back surface with a laser beam and the like. The substrate with conductive film is formed in which a conductive film is formed on one of the main surfaces of a mask blank substrate used in lithography, wherein an intermediate layer having a stress adjustment function is provided between the substrate and the conductive film, and transmittance of a laminated film including the intermediate layer and the conductive film for light having a wavelength of 532 nm is not less than 20%.

### CROSS REFERENCE TO RELATED APPLICATIONS

This application is the U.S. National Phase application of International Application No. PCT/JP2018/000961, filed Jan. 16, 2018, and which claims priority to Japanese Application No. 2017-005773, filed Jan. 17, 2017, and Japanese Application No. 2017-039100, filed on Mar. 2, 2017. The contents of these earlier filed applications are hereby incorporated by reference herein in their entirety.

### TECHNICAL FIELD

The present disclosure relates to a substrate with conductive film, substrate with multilayer reflective film, reflective mask blank and reflective mask for manufacturing an exposure mask used in applications such as the manufacturing of a semiconductor device, and to a method for manufacturing a semiconductor device.

### BACKGROUND ART

The types of light sources of exposure apparatuses used in the manufacturing of semiconductors are evolving while gradually using shorter wavelengths, as is indicated by the g-line having a wavelength of 436 nm, i-line having a wavelength of 365 nm, KrF lasers having a wavelength of 248 nm and ArF lasers having a wavelength of 193 nm, and EUV lithography using extreme ultraviolet (EUV) light, in which the wavelength is in the vicinity of 13.5 nm, has been developed in order to realize transfer of even finer patterns. In EUV lithography, a reflective mask is used due to the small number of materials that are transparent to EUV light. In this reflective mask, the basic structure consists of mask structure in which a multilayer reflective film that reflects exposure light is formed on a low thermal expansion substrate and a desired transfer pattern is formed on a protective film for protecting the multilayer reflective film. In addition, based on the configuration of the transfer pattern, typical examples of reflective masks consist of binary reflective masks having a comparatively thick absorber pattern that adequately absorbs EUV light, and phase shift reflective masks (halftone phase shift reflective masks) composed of a comparatively thin absorber pattern that generates reflected light in which the phase is nearly completely inverted (phase inversion of about 180° C.) relative to light reflected from the multilayer reflective film. Phase shift reflective masks (halftone phase shift reflective masks) allow the obtaining of high transferred optical image contrast due to phase shift effects in the same manner as transmissive optical phase shift masks, thereby making it possible to improve resolution. In addition, a highly accurate, fine phase shift pattern can be formed due to the thin film thickness of the absorber pattern (phase shift pattern) of the phase shift reflective mask.

Multilayer reflective films and absorber films are typically deposited using a deposition method such as sputtering. During this deposition, a reflective mask blank substrate is supported by a support means in the deposition apparatus. An electrostatic chuck is used for the substrate support means. Consequently, a conductive film (back side conductive film) is formed on the back side of a glass substrate or other insulated reflective mask blank substrate (side on the opposite side from the surface on which a multilayer reflective film and the like is formed) in order to promote immobilization of the substrate by the electrostatic chuck.

A substrate with conductive film used in the manufacturing of reflective mask blanks for EUV lithography is described as an example of a substrate with conductive film in Patent Document 1, wherein the conductive film contains chromium (Cr) and nitrogen (N), the average concentration of N in the conductive film is not less than 1 at % to less than 40 at %, the crystalline state of at least the surface of the conductive film is amorphous, the surface roughness (rms) of the conductive film is not more than 0.5 nm, and the conductive film is a graded composition film in which the concentration of N in the conductive film changes along the direction of thickness of the conductive film so that the N concentration on the substrate side decreases while the N concentration on the surface side increases.

Patent Document 2 describes a method for correcting errors in a transfer mask for photolithography. More specifically, Patent Document 2 describes that errors in a transfer mask are corrected by modifying a substrate surface or substrate interior by locally irradiating a transfer mask substrate with a femtosecond laser pulse. Patent Document 2 lists a sapphire laser (wavelength: 800 nm) and Nd-YAG laser (wavelength: 532 nm) as examples of lasers generating femtosecond laser pulses.

Patent Document 3 describes a substrate for a photolithography mask that contains a coating deposited on the rear side of a substrate. Patent Document 3 describes that the coating contains at least one first layer containing at least one metal and at least one second layer containing at least one metal nitride. In addition, it is described that the at least one metal includes nickel (Ni), chromium (Cr), aluminum (Al), gold (Au), silver (Ag), copper (Cu), titanium (Ti), tungsten (W), indium (In), platinum (Pt), molybdenum (Mo), rhodium (Rh) and/or zinc (Zn), and/or at least two mixtures of these metals.

### PRIOR ART DOCUMENTS

### Patent Documents

[Patent Document 1] JP 4978626 B

[Patent Document 2] JP 5883249 B

[Patent Document 3] JP 6107829 B

### DISCLOSURE OF THE INVENTION

### Problems to be Solved by the Invention

Patent Document 2 describes a method for correcting errors in a mask for photolithography with a laser beam. When applying the technology described in Patent Document 2 to a reflective mask, the laser beam is thought to be radiated from the side of the second main surface (back side) of the substrate. However, since a back side conductive film (to also be simply referred to as a “conductive film”) composed of a material containing chromium (Cr) and the like is disposed on the side of the second main surface of the reflective mask substrate, the problem arises of it being difficult for the laser beam to penetrate the back side conductive film.

Therefore, an aspect of the present disclosure is to provide a reflective mask that corrects misalignment of the reflective mask from the back surface with a laser beam and the like. In addition, an aspect of the present disclosure is to obtain a substrate with conductive film, substrate with multilayer reflective film and reflective mask blank for fabricating a reflective mask capable of correcting misalignment of the reflective mask from the back surface with a laser beam and the like.

Means for Solving the Problems

The present disclosure employs the following configurations in order to solve the aforementioned problems.

(Configuration 1)

A substrate with conductive film in which a conductive film is formed on one of the main surfaces of a mask blank substrate used in lithography; wherein

an intermediate layer having a stress adjustment function is provided between the substrate and the conductive film, and

transmittance of a laminated film including the intermediate layer and the conductive film for light having a wavelength of 532 nm is not less than 20%.

(Configuration 2)

The substrate with conductive film described in Configuration 1, wherein the intermediate layer is composed of a material containing at least one element selected from silicon (Si), tantalum (Ta) and chromium (Cr).

(Configuration 3)

The substrate with conductive film described in Configuration 1 or 2, wherein the intermediate layer is composed of a material containing at least one substance selected from Si₃N₄, SiO₂, TaO, TaON, TaCON, TaBO, TaBON, TaBCON, CrO, CrON, CrCON, CrBO, CrBON and CrBCON.

(Configuration 4)

The substrate with conductive film described in any of Configurations 1 to 3, wherein the film thickness of the intermediate layer is 1 nm to 200 nm.

(Configuration 5)

The substrate with conductive film described in any of Configurations 1 to 4, wherein the conductive film is composed of a material containing at least one element selected from platinum (Pt), gold (Au), aluminum (Al) and copper (Cu).

(Configuration 6)

A substrate with multilayer reflective film in which a multilayer reflective film, obtained by alternately laminating a high refractive index layer and a low refractive index layer, is formed on the main surface on the opposite side from the side on which the conductive film of the substrate with conductive film described in any of Configurations 1 to 5 is formed.

(Configuration 7)

The substrate with multilayer reflective film described in Configuration 6, wherein a protective film is formed on the multilayer reflective film.

(Configuration 8)

A reflective mask blank in which an absorber film is formed on the multilayer reflective film of the substrate with multilayer reflective film described in Configuration 6, or on the protective film described in Configuration 7.

(Configuration 9)

A reflective mask having an absorber pattern in which the absorber film in the reflective mask blank described in Configuration 8 is patterned.

(Configuration 10)

A method for manufacturing a semiconductor device having a step for placing the reflective mask described in Configuration 9 in an exposure apparatus having an exposure light source that emits EUV light, and transferring a transfer pattern to a resist film formed on a transferred substrate.

[Effects of the Invention]

According to the reflective mask blank of the present disclosure, a reflective mask can be provided that is capable of correcting misalignment of the reflective mask from the back side with a laser beam and the like. In addition, according to the present disclosure, a substrate with conductive film, a substrate with multilayer reflective film and a reflective mask blank can be obtained for producing a reflective mask capable of correcting misalignment of the reflective mask from the back side with a laser beam and the like.

### BRIEF DESCRIPTION OF THE DRAWINGS

FIG. 1 is a cross-sectional schematic diagram showing the essential portion of one example of the configuration of a substrate with conductive film according to the present disclosure.

FIG. 2 is a cross-sectional schematic diagram of the essential portion for explaining the general configuration of the reflective mask blank according to the present disclosure.

FIG. 3 depicts cross-sectional schematic diagrams of the essential portions of a process for fabricating a reflective mask from a reflective mask blank.

FIG. 4 is a graph indicating the relationship between the thickness of an absorber film of Example 1 and reflectance to light having a wavelength of 13.5 nm.

FIG. 5 is a graph indicating the transmittance spectrum for each film thickness of a back side conductive film composed of a Pt film.

FIG. 6 is a graph indicating changes in transmittance versus changes in film thickness of an intermediate layer in the case of using a Pt film for the back side conductive film and using a Si3N₄ film for the intermediate layer.

FIG. 7 is a graph indicating changes in transmittance versus changes in film thickness of an intermediate layer in the case of using a Pt film for the back side conductive film and using a Sift film for the intermediate layer.

FIG. 8 is a graph indicating changes in transmittance versus changes in film thickness of an intermediate layer in the case of using a Pt film for the back side conductive film and using a TaBO film for the intermediate layer.

FIG. 9 is a graph indicating changes in transmittance versus changes in film thickness of an intermediate layer in the case of using a Pt film for the back side conductive film and using a CrOCN film for the intermediate layer.

### MODE FOR CARRYING OUT THE INVENTION

The following provides a detailed explanation of embodiments of the present disclosure with reference to the drawings. Furthermore, the following embodiments are merely aspects used when embodying the present disclosure and are not intended to limit the present disclosure to the scope thereof. Furthermore, in the drawings, the same reference symbols are used to indicate the same or equivalent portions and explanations thereof may be simplified and/or omitted.

The present disclosure is a substrate with conductive film in which a conductive film is formed on one of the main surfaces of a mask blank substrate. Among the main surfaces of the mask blank substrate, the main surface on which the conductive film (to also be referred to as a “back surface conductive film”) is formed is referred to as the “back surface”. In addition, the present disclosure is a substrate with multilayer reflective film in which a multilayer reflective film, obtained by alternately laminating a high refractive index layer and a low refractive index layer, is formed on the main surface on which the conductive film of the substrate with conductive film is not formed (to also be referred to as the “front surface”).

In addition, the present disclosure is a reflective mask blank having a mask blank multilayer film containing an absorber film on a multilayer reflective film of a substrate with multilayer reflective film.

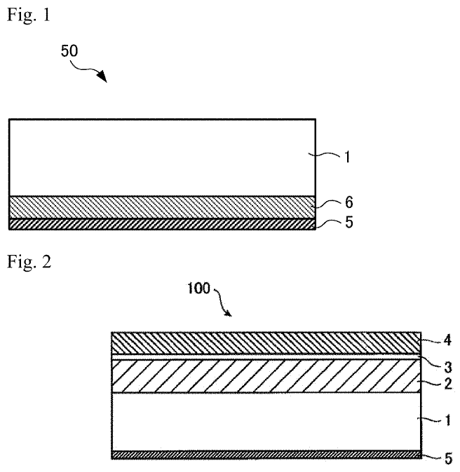

FIG. 1 is a schematic diagram showing one example of a substrate with conductive film 50 of the present disclosure. The substrate with conductive film 50 of the present disclosure has a structure in which a back surface conductive film 5 is formed on the back surface of a mask blank substrate 1. Furthermore, in the present description, the substrate with conductive film 50 refers to that in which the back surface conductive film 5 is at least formed on the back surface of the substrate 1, and that in which a multilayer reflective film 2 is formed on another main surface or that in which an absorber film 4 is further formed on another main surface (reflective mask blank 100) are included in the substrate with conductive film 50. In the present description, the back surface conductive film 5 may also be simply referred to as the conductive film 5.

<Configuration of Reflective Mask Blank and Fabrication Method Thereof>

FIG. 2 is a cross-sectional schematic diagram of the essential portion for explaining the configuration of the reflective mask blank according to the present disclosure. As shown in this diagram, the reflective mask blank 100 has the substrate 1, the multilayer reflective film 2, which reflects exposure light in the form of EUV light, formed on the side of the first main surface (front surface), a protective film 3 provided to protect the multilayer reflective film 2 and formed with a material demonstrating resistance to etchant and cleaning solutions used when patterning an absorber film 4 to be subsequently described, and the absorber film 4 that absorbs EUV light, laminated in this order. In addition, a back surface conductive film 5 for electrostatic chucking is formed on the side of the second main surface (back surface) of the substrate 1.

In the present description, “having a multilayer reflective film 2 on a main surface of the mask blank substrate 1” includes not only to the case of the multilayer reflective film 2 being disposed in contact with the surface of the mask blank substrate 1, but also the case of having another film between the mask blank substrate 1 and the multilayer reflective film 2. This applies similarly to other films as well. For example, “having a film B on a film A” includes not only the case of film A and film B being disposed in direct contact, but also the case of having another film between the film A and the film B. In addition, in the present description, “film A being disposed in direct contact with film B” refers to film A and film B being disposed in direct contact without interposing another film between the film A and the film B.

In the present description, the intermediate layer 6 being, for example, “composed of a material containing at least one element selected from silicon (Si), tantalum (Ta) and chromium (Cr)” means that the intermediate layer 6 is at least substantially composed of a material containing at least one element selected from silicon (Si), tantalum (Ta) and chromium (Cr). In addition, the intermediate layer 6 being “composed of a material containing at least one element selected from silicon (Si), tantalum (Ta) and chromium (Cr)” may also mean that the intermediate layer 6 is only composed of a material containing at least one element selected form silicon (Si), tantalum (Ta) and chromium (Cr). In addition, either of these cases includes the containing of unavoidably contaminating impurities in the intermediate layer 6. This applies to other films such as the conductive film 5.

The following provides an explanation for each layer.

<<Substrate>>

The substrate 1 is for preventing strain in the absorber pattern caused by heat during exposure by EUV light, and that having a low thermal expansion coefficient within the range of 0±5 ppb/° C. may be used. Examples of materials having a low thermal expansion coefficient within this range that can be used include SiO₂-TiO₂-based glass and multi-component glass ceramics.

The first main surface on the side on which a transfer pattern of the substrate 1 (which is composed by an absorber film to be subsequently described) is subjected to surface processing so as to obtain a high degree of flatness at least from the viewpoints of pattern transfer accuracy and positional accuracy. In the case of EUV exposure, the degree of flatness in a region measuring 132 mm×132 mm of the main surface on the side on which the transfer pattern of the substrate 1 is formed may be not more than 0.1 μm, may be not more than 0.05 μm and may be not more than 0.03 μm. In addition, the second main surface on the opposite side from the side on which the absorber film is formed is the side that is electrostatically chucked when placing in an exposure apparatus, and the degree of flatness in a region measuring 132 mm×132 mm may be not more than 0.1 μm, may be not more than 0.05 μm and may be not more than 0.03 μm. Furthermore, the degree of flatness on the side of the second main surface of the reflective mask blank 100 in a region measuring 142 mm×142 mm may be not more than 1 μm, may be not more than 0.5 μm and may be not more than 0.3 μm.

In addition, the high level of the surface smoothness of the substrate 1 is also an extremely important parameter, and the surface roughness of the first main surface of the substrate 1 on which the absorber pattern for transfer is formed in terms of room mean square (RMS) roughness may be not more than 0.1 nm. Furthermore, surface smoothness can be measured with an atomic force microscope.

Moreover, the substrate 1 may have high rigidity to prevent deformation caused by film stress of a film formed thereon (such as the multilayer reflective film 2). In particular, the substrate 1 may have a high Young's modulus of not less than 65 GPa.

<<Multilayer Reflective Film>>

The multilayer reflective film 2 imparts a function that reflects EUV light in a reflective mask, and the multilayer reflective film 2 has the configuration of a multilayer film in which each layer composed mainly of elements having different refractive indices is cyclically laminated.

In general, a multilayer film obtained by alternately laminating roughly 40 to 60 cycles of a thin film of high refractive index material in the form of a light element or compound thereof (high refractive index layer) and a thin film of a low refractive index material in the form of a heavy element or compound thereof (low refractive index layer) is used for the multilayer reflective film 2. The multilayer film may have a structure obtained by laminating for a plurality of cycles, with one cycle consisting of a laminated structure of a high refractive index layer/low refractive index layer, obtained by laminating a high refractive index layer and low refractive index layer in that order starting from the side of the substrate 1, or the multilayer film may have a structure obtained by laminating for a plurality of cycles, with one cycle consisting of a laminated structure of low refractive index layer/high refractive index layer, obtained by laminating a low refractive index layer and high refractive index layer in that order starting from the side of the substrate 1. Furthermore, the layer on the uppermost side of the multilayer reflective film 2, namely the front side layer of the multilayer reflective film 2 on the opposite side from the substrate 1, may be a high refractive index layer. In the aforementioned multilayer film, in the case of laminating for a plurality of cycles, with one cycle consisting of a laminated structure obtained by laminating a high refractive index layer/low refractive index layer obtained by laminating a high refractive index layer and a low refractive index layer in that order on the substrate 1, the uppermost layer is a low refractive index layer. In this case, the low refractive index layer ends up being oxidized easily if it composes the uppermost side of the multilayer reflective film 2 and reflectance of the reflective mask decreases. Consequently, the multilayer reflective film 2 may be obtained by further forming a high refractive index layer on the low refractive index layer of the uppermost layer. On the other hand, in the aforementioned multilayer film, in the case of laminating for a plurality of cycles, with one cycle consisting of a laminated structure of a low refractive index layer/high refractive index layer obtained by laminating a low refractive index layer and high refractive index layer in that order starting from the side of the substrate 1, since the uppermost layer is a high refractive index layer, the multilayer reflective film 2 can be used as is.

In the present embodiment, a layer containing silicon (Si) is used as a high refractive index layer. The material containing Si may be Si alone or a Si compound containing Si and boron (B), carbon (C), nitrogen (N) and oxygen (O). As a result of using a layer containing Si as a high refractive index layer, a reflective mask for EUV lithography is obtained that demonstrates superior reflectance of EUV light. In addition, in the present embodiment, a glass substrate may be used for the substrate 1. Si also demonstrates superior adhesiveness with glass substrates. In addition, a metal selected from molybdenum (Mo), ruthenium (Ru), rhodium (Rh) and platinum (Pt), or an alloy thereof, is used as a low refractive index layer. For example, a Mo/Si cyclically laminated film, obtained by alternately laminating an Mo film and Si film for about 40 to 60 cycles, may be used for the multilayer reflective film 2 with respect to EUV light having a wavelength of 13 nm to 14 nm. Furthermore, the uppermost layer of the multilayer reflective film 2 in the form of a high refractive index layer may be formed with silicon (Si), and a silicon oxide layer containing silicon and oxygen may be formed between the uppermost layer (Si) and the Ru-based protective film 3. As a result, resistance of the mask to cleaning can be improved.

The reflectance of this reflective multilayer film 2 alone is normally not less than 65% and the upper limit thereof is normally 73%. Furthermore, the thickness and number of cycles of each layer composing the multilayer reflective film 2 are suitably selected according to exposure wavelength so as to satisfy Bragg's law. Although multiple layers each of a high refractive index layer and low refractive index layer are present in the multilayer reflective film 2, the high refractive index layers and low refractive index layers are not required to have the same thickness. In addition, the film thickness of the Si layer of the uppermost side of the multilayer reflective film 2 can be adjusted within a range that does not cause a decrease in reflectance. Film thickness of the Si on the uppermost side (high refractive index layer) can be 3 nm to 10 nm.

Methods for forming the multilayer reflective film 2 are known in the art. For example, each layer of the multilayer reflective film 2 can be deposited by ion beam sputtering to form the multilayer reflective film 2. In the case of the aforementioned Mo/Si cyclically laminated film, a Si film having a film thickness of about 4 nm is first deposited on the substrate 1 by ion beam sputtering using a Si target, after which an Mo film having a film thickness of about 3 nm is deposited using an Mo target, defining this procedure as constituting one cycle, followed by forming the multilayer reflective film 2 by laminating for 40 to 60 cycles (with the layer on the uppermost side being a Si layer). In addition, when depositing the multilayer reflective film 2, the multilayer reflective film 2 may be formed by ion beam sputtering by supplying krypton (Kr) ion particles from an ion source.

<<Protective Film>>

The protective film 3 is formed on the multilayer reflective film 2 in order to protect the multilayer reflective film 2 from etching and cleaning in the process for manufacturing a reflective mask to be subsequently described. In addition, the protective film 3 also serves to protect the multilayer reflective film 2 when repairing opaque defects in the absorber pattern using an electron beam (EB). Here, although FIG. 2 depicts the case of a single layer of the protective film 3, the protective film 3 can also be composed of a laminated structure consisting of not less than three layers. For example, the protective film 3 may be in the form of a protective film 3 that uses layers composed of a substance containing the aforementioned Ru for the lowermost layer and uppermost layer and interposing a metal or alloy other than Ru between the lowermost layer and uppermost layer. For example, the protective film 3 can be composed of a material containing ruthenium as the main component thereof. Namely, the material of the protective film 3 can consist of Ru metal alone or may be a Ru alloy containing at least one type of metal selected from titanium (Ti), niobium (Nb), molybdenum (Mo), zirconium (Zr), yttrium (Y), boron (B), lanthanum (La), cobalt (Co and rhenium (Re) in the Ru, and may also contain nitrogen. Such a protective film 3 is particularly effective in the case the absorber film 4 consists of a Co—X amorphous metal or Ni—X amorphous metal material, and the absorber film 4 is patterned by dry etching using a Cl-based gas.

The Ru content ratio of this Ru alloy is not less than 50 at % to less than 100 at %, may be not less than 80 at % to less than 100 at %, and may be not less than 95 at % to less than 100 at %. In the case the Ru content ratio of the Ru alloy is not less than 95% to less than 100 at % in particular, the protective film 3 can also be provided with mask cleaning resistance, an etching stop function used when etching the absorber film as well as a protective film function for preventing time-based changes in the multilayer reflective film while suppressing diffusion of a constituent element of the multilayer reflective film (silicon) into the protective film and adequately ensuring reflectance of EUV light.

In the case of EUV lithography, since there are few substances that are transparent with respect to exposure light, it is not technically easy to provide a EUV pellicle that prevents adhesion of foreign matter to the surface of the mask pattern. Thus, pellicle-less applications not employing a pellicle have become common. In addition, in the case of EUV lithography, exposure contamination occurs in the manner of deposition of a carbon film or growth of an oxide film on the mask caused by EUV exposure. Consequently, it is necessary to remove foreign matter and contamination on the mask by frequently carrying out cleaning when a EUV reflective mask is used to manufacture a semiconductor device. Consequently, the EUV reflective mask is required to demonstrate considerably more resistance to mask cleaning in comparison with transmissive masks for photolithography. The use of a Ru-based protective film containing Ti makes it possible to particularly enhance cleaning resistance to cleaning solutions such as sulfuric acid, sulfuric peroxide mixture (SPM), ammonia, ammonia peroxide mixture (APM), OH radical cleaning solution or ozone water having a concentration of not more than 10 ppm, thereby satisfying the requirement of being resistant to mask cleaning.

There are no particular limitations on the thickness of this protective film 3 composed of Ru or an alloy thereof provided it allows the function of a protective film to be demonstrated. From the viewpoint of reflectance of EUV light, the thickness of the protective film 3 may be 1.0 nm to 8.0 nm and may be 1.5 nm to 6.0 nm.

A deposition method similar to known deposition methods can be used to form the protective film 3 without any particular restrictions. Specific examples thereof include sputtering and ion beam sputtering.

<<Absorber Film>>

The reflective mask blank 100 has the absorber film 4 on the aforementioned substrate with multilayer reflective film. Namely, the absorber film 4 is formed on the multilayer reflective film 2 (or on the protective film 3 in the case the protective film 3 has been formed).

There are no particular limitations on the material of the absorber film 4 provided it has a function that absorbs EUV light and can be processed by etching and the like (and may be etched by dry etching with chlorine (Cl)-based and fluorine (F)-based gas). Tantalum (Ta) alone or a material containing Ta can be used as a material having such functions.

Examples of materials containing Ta include materials containing Ta and B, materials containing Ta and N, materials containing Ta, B and at least one of O and N, materials containing Ta and Si, materials containing Ta, Si and N, materials containing Ta and Ge, materials containing Ta, Ge and N, materials containing Ta and Pd, materials containing Ta and Ru, and materials containing Ta and Ti.

The absorber film 4 can be formed from a material containing at least one material selected from the group consisting of Ni alone, material containing Ni, Cr alone, material containing Cr, Ru alone, material containing Ru, Pd alone, material containing Pd, Mo alone and material containing Mo.

In addition, in the case of EUV lithography, a projection optical system is used that is composed of a large number of reflective mirrors because of optical transmittance. EUV light is then allowed to enter the reflective mask on an angle so that these multiple reflective mirrors do not block the projected light (exposure light). At present, the incident angle is commonly made to be 6° with respect to a plane perpendicular to the reflective mask substrate. Studies are proceeding in the direction of improving the numerical aperture (NA) of the projection optical system while also obtaining an angle at a steeper inclination of about 8°.

EUV lithography has a unique problem referred to as the shadowing effect as a result of exposure light entering on an oblique angle. The shadowing effect refers to a phenomenon of change of the dimensions and/or location of a pattern formed by transfer due to the formation of shadows caused by the entry of exposure light into an absorber pattern having a three-dimensional structure on an oblique angle. The three-dimensional structure of the absorber pattern serves as a wall that allows the formation of a shadow on the shady side, thereby causing the dimensions or location of the pattern formed by transfer to change. For example, differences occur in the dimensions and location of two transfer patterns resulting in a decrease in transfer accuracy between the case of the orientation of the arranged absorber pattern being parallel to the direction of oblique incident light and the case of the orientation of the arranged absorber pattern being perpendicular.

The electrical properties and performance of semiconductor devices improve the finer the pattern and the greater the accuracy of the pattern dimensions and location, and in order to improve degree of integration and reduce chip size, EUV lithography requires an even higher level of high-precision, fine-dimension pattern transfer performance than in the prior art. At present, half-pitch 16 nm (hp16 nm) generation-compatible ultrafine and high-precision pattern formation is required. In order to satisfy this requirement, even greater reductions in thickness are required in order to reduce shadowing effects. In the case of EUV exposure in particular, it may reduce film thickness of the absorber film (phase shift film) 4 to less than 60 nm and may be to no more than 50 nm.

Ta has been used as a material that forms the absorber film (phase shift film) of the reflective mask blank 100. However, the refractive index of Ta in EUV light (having a wavelength of 13.5 nm, for example) is about 0.943, and even if phase shift effects are utilized, the limit on the reduction in thickness of an absorber film (phase shift film) formed with Ta alone is 60 nm. In order to reduce thickness even further, a metal material, for example, having a large extinction coefficient k at a wavelength of 13.5 nm can be used for the absorber film 4 of a binary reflective mask blank. Examples of metal materials having a large extinction coefficient at a wavelength of 13.5 nm include cobalt (Co) and nickel (Ni). However, since Co and Ni are magnetic, when electron beam lithography is carried out on a resist film on an absorber film deposited using these materials, there is the risk of the possibility of being unable to draw the pattern according to the design value.

Therefore, in consideration of the aforementioned points, the absorber film 4 employs the following configuration in order to obtain the reflective mask blank 100 that is capable of further reducing the shadowing effect of the reflective mask as well as forming a fine and highly accurate phase shift pattern. Namely, the absorber film 4 has a function that absorbs EUV light and is composed of a material that contains at least one element among cobalt (Co) and nickel (Ni) as a material that can be processed by dry etching. As a result of the absorber film 4 employing a configuration that contains cobalt (Co) and nickel (Ni), extinction coefficient k can be made to be not less than 0.035 and the thickness of the absorber film 4 can be reduced. In addition, as a result of using an amorphous metal for the absorber film 4, etching rate can be increased and pattern shape can be improved, thereby making it possible to improve processing characteristics.

Examples of amorphous metals include those obtained by adding at least one element (X) among tungsten (W), niobium (Nb), tantalum (Ta), titanium (Ti), zirconium (Zr), hafnium (Hf), yttrium (Y) and phosphorous (P) to at least one element among cobalt (Co) and nickel (Ni).

Among these added elements (X), W, Nb, Ta, Ti, Zr, Hf and Y are nonmagnetic materials. Consequently, by forming a Co—X or Ni—X alloy by adding these materials to Co or Ni, a soft magnetic amorphous metal can be obtained and the magnetism of the materials composing the absorber film 4 can be suppressed. As a result, electron beam drawing is not affected and favorable pattern drawing can be carried out.

In the case the added element (X) is Zr, Hf and Y, the content ratios of the added element (X) in a Co—X alloy or Ni—X alloy may be not less than 3 at % and may be not less than 10 at %. In the case the content ratios of Zr, Hf or Y are less than 3 at %, it becomes difficult to make the Co—X alloy or Ni—X alloy amorphous.

In addition, in the case the added element (X) is W, Nb Ta and Ti, the content ratios of the added element (X) in a Co—X alloy or Ni—X alloy are preferably not less than 10 at % and may be not less than 15 at %. In the case the content ratios of W, Nb, Ta and Ti are less than 10 at %, it becomes difficult to make the Co—X alloy or Ni—X alloy amorphous.

In the case the added element (X) is P, by making the content ratio of P in NiP may be not less than 9 at % and may be not less than 19 at %, a nonmagnetic amorphous metal can be obtained and the magnetism of materials composing the absorber film can be eliminated. In the case the content ratio of P is less than 9 at %, NiP becomes magnetic and it becomes difficult to make NiP amorphous.

In addition, the content ratio of the added element (X) in a Co—X alloy or Ni—X alloy is adjusted so that the extinction coefficient k at a wavelength of 13.5 nm is not less than 0.035. Thus, the content ratio of the added element (X) may be not more than 97 at %, may be not more than 50 at % and even may be not more than 24 at %. In particular, the content ratios of Nb, Ti, Zr and Y, which alone have extinction coefficients of less than about 0.035, may be not more than 24 at %.

In addition, another element such as (N), oxygen (O), carbon (C) or boron (B) may also be contained in addition to the aforementioned added element (X) within a range that does not have a significant effect on refractive index or extinction coefficient.

The absorber film 4 composed of such amorphous metals can be formed by a known method in the manner of a magnetron sputtering method such as DC sputtering or RF sputtering. In addition, sputtering can be carried out using a Co—X metal target or Ni—X metal target, or co-sputtering can be carried out using a Co target or Ni target and an added metal (X) target.

The absorber film 4 may be used for EUV light as a binary type of reflective mask blank, or may be an absorber film 4 having a phase shift function in consideration of the phase difference of EUV light that is used as a phase shift type of reflective mask blank.

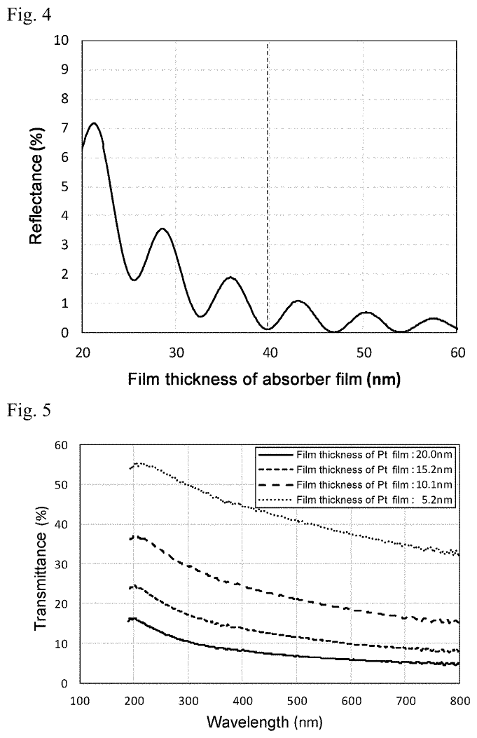

In the case of using the absorber film 4 for the absorbing EUV light, film thickness is set so that the reflectance of the EUV light with respect to the absorber film 4 is not more than 2% and may be not more than 1%. In addition, in order to suppress the shadowing effect, the film thickness of the absorber film is required to be less than 60 nm and may be not more than 50 nm. For example, as indicated by the dotted line in FIG. 4, in the case of having formed the absorber film 4 with a NiTa alloy film, reflectance at 13.5 nm can be made to be 0.11% by making the film thickness 39.8 nm.

In the case the absorber film 4 has a phase shift function, the portion, where the absorber film 4 is formed, reduces EUV light and reflects a portion of the light at a level that does not have a detrimental effect on pattern transfer, and a desired phase difference is formed with reflected light reflected from a field portion that is reflected from the multilayer reflective film 2 through the protective film 3. The absorber film 4 is formed so that the phase difference between light reflected from the absorber film 4 and light reflected from the multilayer reflective film 2 is from 160° to 200°. Image contrast of a projected optical image improves due to mutual interference at a pattern edge of light differing in phase as a result of being inverted by 180°. Resolution improves accompanying the improvement in image contrast resulting in a wider range for various types of tolerance relating to exposure such as exposure quantity tolerance or focus tolerance. Although varying according to the pattern and exposure conditions, a general indicator of reflectance of the absorber film 4 for obtaining this phase shift effect is not less than 1% in terms of absolute reflectance and not less than 2% in terms of reflection ratio relative to the multilayer reflective film 2 (provided with the protective film).

The material of the absorber film (phase shift film) 4 may be a TaTi-based material containing tantalum (Ta) and titanium (Ti). Examples of the TaTi-based material include TaTi alloys and TaTi compounds containing at least one of oxygen, nitrogen, carbon and born in the TaTi alloy. Examples of TaTi compounds that can be applied for the TaTi compound include TaTiN, TaTiO, TaTiON, TaTiCON, TaTiB, TaTiBN, TaTiBO, TaTiBON and TaTiBCON. Since Ti has a small extinction coefficient in comparison with Ta, reflectance sufficient for obtaining a phase shift effect can be obtained. For example, the refractive index n of a TaTiN film at 13.5 nm is about 0.937 while the extinction coefficient k is about 0.030. The absorber film (phase shift film) 4 can be set to a film thickness that yields desired values for reflectance and phase difference. More specifically, film thickness of the phase shift film can be set to less than 60 nm and may be not more than 50 nm. In the case of having formed the phase shift film (absorber film 4) with a TaTiN film, relative reflectance with respect to the multilayer reflective film (with protective film) is 5.4% and phase difference is about 169° at a film thickness of 46.7 nm, while relative reflectance with respect to the multilayer reflective film (with protective film) is 6.6% and phase difference is about 180° at a film thickness of 51.9 nm. Furthermore, relative reflectance refers to reflectance of the phase shift film with respect to EUV light when based on absolute reflectance in the case of EUV light having been reflected after directly entering the multilayer reflective film (with protective film).

In addition, the TaTi-based material is a material that can be dry etched with chlorine (Cl)-based gas substantially free of oxygen. As was previously described, an example of a material that allows the obtaining of a phase shift effect is Ru, and since Ru has a low etching rate and is difficult to process and repair, problems with processability may occur in the case of having formed the phase shift film with a material containing a TaRu alloy.

The ratio of Ta to Ti of the TaTi-based material may be 4:1 to 1:4.

A phase shift film (absorber film 4) composed of this TaTi-based material can be formed by a known method in the manner of a magnetron sputtering method such as DC sputtering or RF sputtering. In addition, sputtering can be carried out using a TaTi alloy target or co-sputtering can be carried out using a Ta target and a Ti target.

The absorber film 4 may be a single layer film or may be a multilayer film composed of a plurality of not less than two layers. In the case of a single layer film, the absorber film 4 is characterized by improved production efficiency since the number of steps during mask blank fabrication can be reduced. In the case of a multilayer film, the optical constants and film thickness are suitably set so that the upper layer film serves as an antireflective film during mask pattern inspections using light. As a result, inspection sensitivity when inspecting the mask pattern using light is improved. Various functions can be added by employing a multilayer film in this manner. In the case the absorber film 4 has a phase shift function, the range over which optical adjustments can be made widens due to the multilayer film, there facilitating the obtaining of desired reflectance. In the case the absorber film 4 is a multilayer film composed of not less than two layers, one of the layers of the multilayer film may be a Co—X amorphous metal or an Ni—X amorphous metal.

In the case the absorber film 4 employs a two-layer structure, the etching gas may differ between the upper layer film and lower layer film. For example, a gas selected from a fluorine-based gas such as CF₄, CHF₃, C₂F₆, C₃F₆, C₄F₆, C₄F₈, CH₂F₂, CH₃F, C₃F₈, SF₆ or F₂, and mixed gases containing these fluorine-based gases and O₂ at a prescribed ratio, can be used for the etching gas of the upper layer film. In addition, a gas selected from a chlorine-based gas such as Cl₂, SiCl₄ and CHCl₃, a mixed gas containing a chlorine-based gas and O₂ at a prescribed ratio, a mixed gas containing a chlorine-based gas and He at a prescribed ratio, and a mixed gas containing a chlorine-based gas and Ar at a prescribed ratio can be used for the etching gas of the lower layer film. Here, if oxygen is contained in the etching gas at the final stage of etching, surface roughening occurs in the Ru-based protective film 3. Consequently, an etching gas not containing oxygen may be used in the over-etching stage when the Ru-based protective film 3 is exposed to etching.

An etching mask film may also be formed on the absorber film 4. A material for which the absorber film 4 has high etching selectivity for the etching mask film is used for the material of the etching mask film. Here, “etching selectivity of B for A” refers to the ratio of the etching rates of the layer on which etching is desired to be carried out in the form of B to the layer where etching is not carried out (layer serving as a mask) in the form of A. More specifically, etching selectivity is specified with the equation “etching selectivity of B to A=etching rate of B/etching rate of A”. In addition, “high selectivity” refers to the value of selectivity as defined above being large relative to a comparison target. Etching selectivity of the absorber film 4 to the etching mask film may be not less than 1.5 and may be not less than 3.

Examples of materials for which the absorber film 4 has high etching selectivity for the etching mask film include chromium and chromium compounds. Thus, in the case of etching the absorber film 4 with a fluorine-based gas, a material composed of chromium or a chromium compound can be used. Examples of chromium compounds include materials containing Cr and at least one element selected from N, O, C and H. In addition, in the case of etching the absorber film 4 with a chlorine-based gas substantially free of oxygen, a material composed of silicon or a silicon compound can be used. Examples of silicon compounds include materials containing Si and at least one element selected from N, O, C and H, and materials such as metallic silicon (metal silicide) containing a metal in silicon or a silicon compound and metal silicon compounds (metal silicide compounds). Examples of metal silicon compounds include materials containing a metal, Si and at least one element selected from N, O, C and H.

The film thickness of the etching mask film may be not less than 3 nm from the viewpoint of obtaining the function of an etching mask of being able to accurately form a transfer pattern on the absorber film 4. In addition, the film thickness of the etching mask film may be not more than 15 nm from the viewpoint of reducing film thickness of the resist film.

<<Back Surface Conductive Film>>

The following provides an explanation of the substrate with conductive film 50 of the present disclosure. As shown in FIG. 1, the substrate with conductive film 50 of the present disclosure can be obtained by forming the prescribed back surface conductive film 5 on one side of the main surfaces of the mask blank substrate 1. In addition, the substrate with conductive film 50 of the present disclosure can be obtained by forming the prescribed back surface conductive film 5 on the side opposite from the side that contacts the multilayer reflective film 2 of the substrate in a substrate with multilayer reflective film.

The substrate with conductive film 50 of the present disclosure has the conductive film 5 (back surface conductive film 5) formed on one surface (back surface) of the main surfaces of the mask blank substrate 1 used in lithography. The intermediate layer 6 having a stress adjustment function is provided between the substrate 1 and the conductive film 5.

The back surface conductive film 5 for electrostatic chucking is normally required to demonstrate an electrical property (sheet resistance) of not more than 100 Ω/□ (Ω/square). The back surface conductive film 5 can be formed by, for example, magnetron sputtering or ion beam sputtering using a target consisting of a metal or metal alloy that is a material of the back surface conductive film 5.

The material of the back surface conductive film 5 is formed at least using a material in which transmittance to light having a wavelength of 532 nm is not less than 20%.

Indium tin oxide (ITO), fluorine-doped tin oxide (FTO), aluminum-doped zinc oxide (AZO) or antimony-doped tin oxide (ATO) may be used for the material this back side conductive film (transparent conductive film) 5 having high transmittance. Making the film thickness of the transparent conductive film to be not less than 50 nm enables the electrical property (sheet resistance) required of the back side conductive film 5 for electrostatic chucking to be not more than 100 Ω/□. For example, the transmittance of an ITO film having a film thickness of 100 nm for a wavelength of 532 nm is about 79.1% and sheet resistance if 50 Ω/□.

In addition, a metal such as platinum (Pt), gold (Au), aluminum (Al) or copper (Cu) may be used as a material of the back side conductive film (transparent conductive film) 5 having high transmittance. In addition, a metal compound containing these metals and at least one of boron, nitrogen, oxygen and carbon can also be used within a range that satisfies the desired transmittance and electrical properties. These metal films make it possible to reduce film thickness in comparison with the aforementioned ITO and the like due to the high electrical conductivity thereof The film thickness of the metal film may be not more than 50 nm and may be not more than 20 nm from the viewpoint of transmittance. In addition, if the film is excessively thin, since sheet resistance tends to increase rapidly, and from the viewpoint of stability during deposition, the film thickness of the metal film may be not less than 2 nm. The transmittance of a Pt film having a film thickness of 10.1 nm with respect to a wavelength of 532 nm is 20.3% and sheet resistance is 25.3 Ω/□.

Moreover, the back surface conductive film 5 may be a single layer film or have a multilayer structure of not less than two layers. In order to improve mechanical durability during electrostatic chucking or improve cleaning resistance, the uppermost layer preferably consists of CrO, TaO or SiO₂. In addition, the uppermost layer may consist of an oxide film of the aforementioned metal films, namely PtO, AuO, AlO or CuO. The thickness of the uppermost layer may be not less than 1 nm, may be not less than 5 nm and even may be not less than 10 nm. The material and film thickness of the back surface conductive film 5 are selected so that transmittance satisfies the requirement of not less than 20%.

As was previously described, although the back surface conductive film 5 is required to have desired values for an electrical property (sheet resistance) and transmittance in the case of radiating a laser beam from the back surface, when the film thickness of the back surface conductive film 5 is reduced in order to satisfy these requirements, different problems may occur. Normally, since the multilayer reflective film 2 has high compressive stress, a convex shape forms on the first main surface of the substrate 1 while a concave shape forms on the second main surface (back surface). On the other hand, stress is adjusted by annealing (heat treatment) of the multilayer reflective film 2 and deposition of the back surface conductive film 5, and is adjusted so as to obtain a reflective mask blank that is flat overall or has only slight depressions in the second main surface. However, this balance is disrupted if the film thickness of the back surface conductive film 5 is excessively thin thereby causing a concave shape in the second main surface (back surface) to end up becoming excessively large. In this case, scratches form in the periphery of the substrate (and particular in the corners) during electrostatic chucking and problems such as film separation or particle generation may occur.

Therefore, the second main surface (back surface) of the substrate with multilayer reflective film of the present disclosure may have a degree of flatness of not more than 300 nm. Furthermore, a convex shape in the present disclosure refers to a surface state in which height distribution of the measured surface when using the focal plane, calculated according to the least squares method from the measured surface, as a reference plane indicates a decreasing trend moving from the center or roughly the center of the substrate towards the edge (outer periphery), when, for example, the surface shape of a surface in a prescribed region containing the center of a main surface of the substrate is measured with a flatness measuring apparatus using interference of light. In addition, degree of flatness is defined in the following manner with a value representing warping (amount of deformation) of the surface as represented by the total indicated reading (TIR). Namely, the absolute value of height difference between the highest location of the substrate surface located above the focal plane and the lowest location of the substrate surface below the focal plane, when the flat surface determined according to the least squares method based on the substrate surface is used as the focal plane and this focal plane is then used as a reference. In the present disclosure, the degree of flatness is taken to be the measured value in an area measuring 142 mm×142 mm.

The intermediate layer 6 may be provided on the substrate side of the back surface conductive film (transparent conductive film) 5 in order to solve the aforementioned problems arising in the case the film thickness of the back surface conductive film is excessively thin. The intermediate layer 6 has a stress adjustment function and allows the obtaining of desired transmittance (for example, not less than 20% at a wavelength of 532 nm) when combined with the transparent conductive substrate.

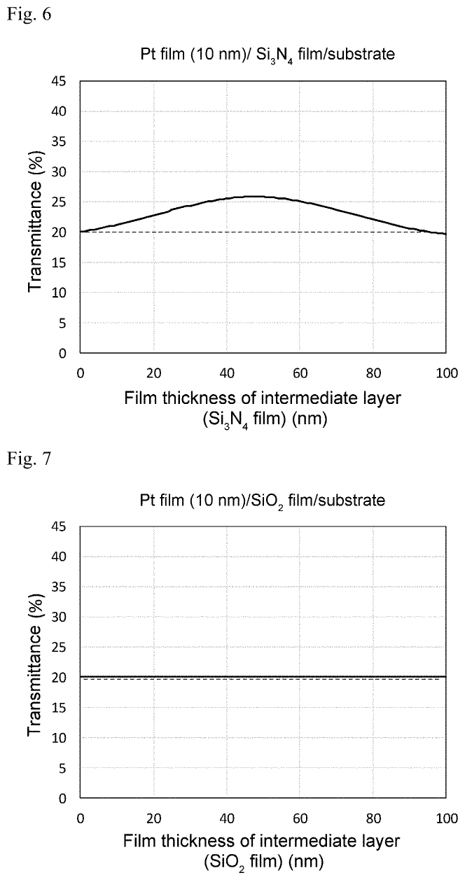

Examples of the material of the intermediate layer 6 include Si₃N₄ and SiO₂. Si₃N₄ has fewer restrictions on film thickness in comparison with other materials due to its high transmittance at a wavelength of 532 nm. For example, in the case of the intermediate layer 6 composed of Si₃N₄, stress can be adjusted over a film thickness range of 1 nm to 200 nm. FIG. 6 shows the results of investigating changes in transmittance versus changes in film thickness of the intermediate layer 6 when irradiating the side of the back surface conductive film 5 with light of a wavelength of 532 nm in the case of using a Pt film having a film thickness of 10 nm for the back surface conductive film 5 on the back surface of the substrate 1 and using a Si₃N₄ film for the intermediate layer 6. According to these results, since a laminated film of the intermediate layer 6 and back surface conductive film 5 demonstrates transmittance of not less than 20% at least over a film thickness range up to 100 nm, the intermediate layer 6 is able to adjust stress over this range. FIG. 7 shows the results of investigating changes in transmittance versus changes in film thickness of the intermediate layer 6 in the case of using a Pt film having a film thickness of 10 nm for the back surface conductive film 5 and using a SiO₂ film for the intermediate layer 6. According to these results, since a laminated film of the intermediate layer 6 and the back surface conductive film 5 demonstrates transmittance of not less than 20% at least over a film thickness range up to 100 nm, the intermediate layer 6 is able to adjust stress over this range.

In the case of using Si₃N₄ and SiO₂ for the materials of the intermediate layer 6, the film thickness of the back surface conductive film 5 composed of a metal film may be 2 nm to 10 nm from the viewpoints of ensuring electrical conductivity and transmittance. In addition, the film thickness of a laminated film of the intermediate layer 6 and the back surface conductive film 5 may be 6 nm to 250 nm and may be 15 nm to 100 nm.

In addition, a Ta-based oxide film or Cr-based oxide film having a small extinction coefficient can be used for the material of the intermediate layer 6. The material of the intermediate layer 6 may have an extinction coefficient at a wavelength of 532 nm of not more than 1.3. Examples of Ta-based oxide films include TaO, TaON, TaCON, TaBO, TaBON and TaBCON. In the case the intermediate layer 6 is composed of a Ta-based oxide film, the oxygen (O) content thereof may be 20 at % to 70 at %. Examples of Cr-based oxide films include CrO, CrON, CrCON, CrBO, CrBON and CrBOCN. In the case the intermediate layer is composed of a Cr-based oxide film, the oxygen (O) content thereof may be 25 at % to 75 at %. Moreover, the material of the intermediate layer 6 may also be an oxide film of the metal film of the aforementioned back surface conductive film 5, or in other words, PtO, AuO, AlO or CuO.

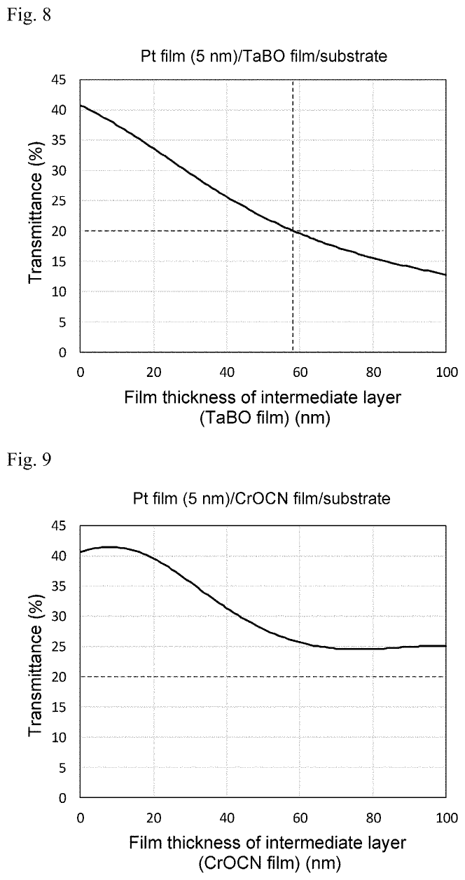

FIG. 8 shows the results of investigating changes in transmittance versus changes in film thickness of the intermediate layer 6 in the case of using a Pt film having a film thickness of 5 nm for the back surface conductive film 5 and using a TaBO film for the intermediate layer 6. According to these results, since a laminated film of the intermediate layer 6 and the back surface conductive film 5 demonstrates transmittance of not less than 20% over a film thickness range of up to 58 nm, the intermediate layer 6 is able to adjust stress over this range. FIG. 9 shows the results of investigating changes in transmittance versus changes in film thickness of the intermediate layer 6 in the case of using a Pt film having a film thickness of 5 nm for the back surface conductive film 5 and using a CrOCN film for the intermediate layer 6. According to these results, since a laminated film of the intermediate layer 6 and the back surface conductive film 5 demonstrates transmittance of not less than 20% at least over a film thickness range up to 100 nm, the intermediate layer 6 is able to adjust stress over this range.

In the case of using a metal oxide film such as a Ta-based oxide film or Cr-based oxide film for the material of the intermediate layer 6, the film thickness of the back surface conductive film 5 composed of a metal film may be 2 nm to 5 nm from the viewpoints of ensuring electrical conductivity and transmittance. In addition, the film thickness of a laminated film of the intermediate layer 6 containing a Ta-based oxide film and the back surface conductive film 5 may be 3 nm to 200 nm and may be 10 nm to 60 nm. The film thickness of a laminated film of the intermediate layer 6 containing a Cr-based oxide film and the back surface conductive film 5 may be 3 nm to 250 nm and may be 10 nm to 100 nm.

In addition, in order to solve the aforementioned problems that occur in the case the film thickness of the back surface conductive film 5 is excessively thin, the second main surface (back surface) of the substrate with conductive film on which the back side conductive film 5 is formed may have a convex shape. A first method for giving the second main surface (back surface) of the substrate with conductive film a convex shape consists of giving the second main surface of the substrate 1 a convex shape prior to depositing the back surface conductive film 5. As a result of preliminarily giving the second main surface of the substrate 1 a convex shape, the shape of the second main surface can be made to be convex even if the back side conductive film 5, composed of, for example, a Pt film having a film thickness of about 10 nm and having small film stress, is deposited and a multilayer reflective film 2 having high compressive stress is deposited.

In addition, a second method for giving the second main surface (back side) of the substrate with conductive film a convex shape consists of annealing (heat treating) at 150° C. to 300° C. after depositing the multilayer reflective film 2. Annealing is may be carried out at a high temperature of not lower than 210° C. Although annealing the multilayer reflective film 2 makes it possible to decrease film stress of the multilayer reflective film, there is a tradeoff between annealing temperature and reflectance of the multilayer reflective film. When depositing the multilayer reflective film 2, in the case of conventional Ar sputtering in which argon (Ar) ion particles are supplied from an ion source, the desired reflectance is not obtained if annealing is carried out at a high temperature. On the other hand, as a result of carrying out Kr sputtering in which krypton (Kr) ion particles are supplied from an ion source, annealing resistance of the multilayer reflective film 2 can be improved and high reflectance can be maintained if annealed at a high temperature. Thus, as a result of annealing at 150° C. to 300° C. after depositing the multilayer reflective film 2 by Kr sputtering, film stress of the multilayer reflective film 2 can be decreased. In this case, even if the back side conductive film 5 composed of, for example, a Pt film having a film thickness of about 10 nm and having low fill stress, is deposited, the shape of the second main surface can be made to have a convex shape.

Moreover, the aforementioned first method and second method may also be combined. Furthermore, film thickness can be thickened in the case of using a transparent conductive film such as an ITO film for the back side conductive film. Consequently, the second main surface (back side) of the substrate with conductive film can be given a convex shape by thickening thickness within a range that satisfies electrical properties.

As a result of giving the second main surface (back side) of the substrate with conductive film a convex shape in this manner, the formation of scratches in the periphery of the substrate (and particularly, the corners) can be prevented during electrostatic chucking.

In addition, the intermediate layer 6 can be given a function that improves adhesiveness with the substrate 1 or inhibits entry of hydrogen from the substrate 1 to the back surface conductive film 5. In addition, the intermediate layer 6 can be given a function that inhibits vacuum ultraviolet light and ultraviolet light (wavelength: 130 nm to 400 nm) referred to as out-of-band light from penetrating the substrate 1 and being reflected by the back surface conductive film 5 in the case of using EUV light for the exposure light source. Examples of materials of the intermediate layer 6 include Si, SiO₂, SiON, SiCO, SiCON, SiBO, SiBON, Cr, CrN, CrON, CrC, CrCN, CrCO, CrCON, Mo, MoSi, MoSiN, MoSiO, MoSiCO, MoSiON, MoSiCON, TaO and TaON. The thickness of the intermediate layer 6 may be not less than 1 nm, may be not less than 5 nm, and even may be not less than 10 nm. Furthermore, it is necessary to select the material and film thickness of the intermediate layer 6 so that the transmittance of a laminated film obtained by laminating the intermediate layer 6 and back surface conductive film 5 satisfies the requirement of being not less than 20%.

In addition, the intermediate layer 6 may be a single layer film or employ a laminated structure consisting of not less than two layers. In the case the intermediate layer 6 employs a laminated structure, a stress adjustment function, hydrogen entry inhibitory function and/or out-of-band light inhibitory function can be given separately to each layer.

<Reflective Mask and Fabrication Method Thereof>

A reflective mask 200 is manufactured using the reflective mask blank 100 of the present embodiment. The following provides only a general explanation, while a detailed explanation is subsequently provided in the examples with reference to the drawings.

The reflective mask blank 100 is prepared, a resist film is formed on the absorber film 4 of the first main surface thereof (not required in the case the reflective mask blank 100 is provided in the form of a resist film), and a desired pattern is drawn (exposed) on this resist film followed by development and rinsing to form a prescribed resist pattern.

In the case of the reflective mask blank 100, an absorber pattern is formed by forming an absorber pattern by etching using this resist pattern as a mask, and then removing the resist pattern by ashing or with a resist stripping solution. Finally, wet cleaning is carried out using an acidic or alkaline aqueous solution.

Here, a chlorine-based gas such as Cl₂, SiCl₄, CHCl₃ or CCl₄, a mixed gas containing a chlorine-based gas and He at a prescribed ratio, or a mixed gas containing a chlorine-based gas and Ar at a prescribed ratio is used for the etching gas of the absorber film 4. Since the etching gas is substantially free of oxygen during etching of the absorber film 4, there is no occurrence of surface roughening of the Ru-based protective film. This gas that is substantially free of oxygen corresponds to an oxygen content in the gas of not more than 5 at %.

According to the aforementioned process, a reflective mask is obtained that exhibits little shadowing effects and has a highly accurate and fine pattern exhibiting little side wall roughness.

<Method of Manufacturing Semiconductor Device>

A desired transfer pattern based on an absorber pattern on the reflective mask 200 can be formed on a semiconductor substrate by carrying out EUV exposure using the reflective mask 200 of the aforementioned present embodiment while suppressing decreases in transfer dimensional accuracy caused by shadowing effects. In addition, since the absorber pattern constitutes a fine and highly accurate pattern with little sidewall roughness, a desired pattern can be formed on a semiconductor substrate with high dimensional accuracy. A semiconductor device having a desired electronic circuit formed thereon can be manufactured with this lithography step in addition to various other steps such as etching of the processed film, formation of an insulating film and conductive film, introduction of dopant or annealing.

In providing a more detailed explanation, the EUV exposure apparatus is composed of components such as a laser plasma light source that generates EUV light, illumination optical system, mask stage system, reduction projection optical system, wafer stage system and vacuum equipment. The light source is provided with components such as a debris entrapment function, a cutoff filter that cuts out light of a long wavelength other than exposure light, and equipment for vacuum differential evacuation. The illumination optical system and reduction projection optical system are composed of reflective minors. The reflective mask 200 for EUV exposure is placed on the mask stage by being electrostatically chucked by the back side conductive film 5 formed on the second main surface thereof.

EUV exposure light is radiated onto the reflective mask 200 via the illumination optical system at an angle inclined from 6° to 8° to the perpendicular plane of the reflective mask. Light reflected from the reflective mask 200 in response to this incident light is guided to the reflective projection optical system in the opposite direction from the incident light, reflected at the same angle as the incident light (specular reflection), and normally at a reduction ratio of ¼, after which the resist on a wafer (semiconductor substrate) placed on the wafer stage is subjected to exposure.

During this time, a vacuum is drawn at least at those locations through which EUV light passes. In addition, this exposure primarily employs scan exposure in which exposure is carried out through a slit by synchronizing and scanning the mask stage and wafer stage at a speed corresponding to the reduction ratio of the reduction projection optical system. A resist pattern can then be formed on a semiconductor substrate by developing this exposed resist film. A mask in the form of a thin film exhibiting little shadowing effects that also has a highly accurate absorber pattern having little sidewall roughness is used in the present disclosure. Consequently, a resist pattern formed on the semiconductor substrate is a desired resist pattern having high dimensional accuracy. As a result of carrying out etching and the like by using this resist pattern as a mask, a prescribed wiring pattern, for example, can be formed on a semiconductor substrate. A semiconductor device is manufactured by going through this type of exposure step, processed film processing step, insulating film and conductive film formation step, dopant introduction step or annealing step and the like.

### EXAMPLES

The following provides an explanation of examples with reference to the drawings. Furthermore, the same reference symbols are used to indicate similar constituents in the examples, and explanations thereof may be simplified or omitted.

### Example 1

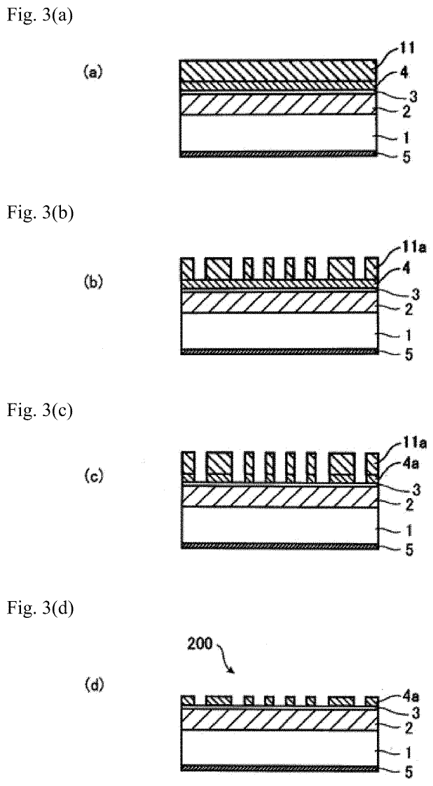

FIG. 3 depicts cross-sectional schematic diagrams of the essential portions of a process for fabricating a reflective mask from a reflective mask blank.

The reflective mask blank 100 has the back surface conductive film 5, the substrate 1, the multilayer reflective film 2, the protective film 3 and the absorber film 4. The absorber film 4 is composed of a material containing a NiTa amorphous alloy. As shown in FIG. 3(a), a resist film 11 is formed on the absorber film 4.

First, an explanation is provided of the reflective mask blank 100.

A 6025 size (approx. 152 mm×152 mm×6.35 mm) low thermal expansion glass substrate in the form of a SiO₂-TiO₂-based glass substrate, of which both the first main surface and second main surface have been polished, is prepared for use as the substrate 1. Polishing consisting of a coarse polishing step, precision polishing step, local processing step and touch polishing step was carried out so as to obtain flat and smooth main surfaces.

The back surface conductive film 5 composed of a Pt film was respectively deposited at film thicknesses of 5.2 nm, 10.1 nm, 15.2 nm and 20.0 nm on the second main surface (back surface) of the SiO₂-TiO₂-based glass substrate 1 by DC magnetron sputtering using a Pt target in an Ar gas atmosphere to fabricate four substrates with conductive film.

The second main surfaces (back surfaces) of the fabricated four substrates with back surface conductive film were irradiated with light of a wavelength of 532 nm followed by measurement of transmittance. As shown in FIG. 5, transmittance values of the four substrates with back surface conductive film were 39.8%, 20.3%, 10.9% and 6.5%, respectively. Namely, those substrates with conductive film having film thicknesses of 5.2 nm and 10.1 nm satisfied the requirement of transmittance of not less than 20%. In addition, measurement of sheet resistance according to the four terminal method yielded values of 57.8 Ω/□, 25.3 Ω/□, 15.5 Ω/□ and 11.2 Ω/□, respectively. Thus, each of these values satisfied the requirement of sheet resistance of not more than 100 Ω/□.

Next, the multilayer reflective film 2 was formed on the main surface (first main surface) of the substrate 1 on the opposite side from the side on which the back surface conductive film 5 was formed for each of the substrates with conductive film having film thicknesses of 5.2 nm and 10.1 nm and for which transmittance was not less than 20%. The multilayer reflective film 2 formed on the substrate 1 was a cyclical multilayer reflective film consisting of Mo and Si in order to obtain a multilayer reflective film suitable for EUV light at a wavelength of 13.5 nm. The multilayer reflective film 2 was formed by using an Mo target and Si target and alternately laminating Mo layers and Si layers on the substrate 1 by ion beam sputtering in an Ar gas atmosphere. First, a Si film was deposited at a thickness of 4.2 nm followed by depositing an Mo film at a thickness of 2.8 nm. When the deposition of these films is taken to be one cycle, the films were similarly deposited for 40 cycles, and finally, a Si film was deposited at a thickness of 4.0 nm to form the multilayer reflective film 2. Although the films were deposited for 40 cycles here, the number of cycles is not limited thereto, but rather the films may be deposited for, for example, 60 cycles. In the case of depositing for 60 cycles, although the number of steps increases more than in the case of 40 cycles, this enables reflectance to EUV light to be enhanced.

Continuing, the protective film 3 composed of a Ru film was deposited at a thickness of 2.5 nm by ion beam sputtering using a Ru target in an Ar gas atmosphere.

Next, the absorber film 4 composed of a NiTa film was formed by DC magnetron sputtering. The NiTa film was deposited at a film thickness of 39.8 nm by reactive sputtering using a NiTa target in a Ar gas atmosphere.

The element ratio of the NiTa film was 80 at % of Ni and 20 at % of Ta. In addition, when the crystal structure of the NiTa film was measured with an X-ray diffraction (XRD) apparatus, it was determined to have an amorphous structure. In addition, refractive index n of the NiTa film at a wavelength of 13.5 nm was approximately 0.947 and the extinction coefficient k thereof was approximately 0.063.

Reflectance of the absorber film 4 composed of the aforementioned NiTa film at a wavelength of 13.5 nm was 0.11% as a result of employing a film thickness of 39.8 nm (FIG. 4).

Next, the reflective mask 200 was fabricated using the aforementioned reflective mask blank 100.

As was previously described, the resist film 11 was formed at a thickness of 100 nm on the absorber film 4 of the reflective mask blank 100 (FIG. 3(a)). A desired pattern was drawn (exposed) on this resist film 11 followed by developing and rinsing to form a prescribed resist pattern 11a (FIG. 3(b)). Next, using the resist pattern 11a as a mask, dry etching of the NiTa film (absorber film 4) was carried out using Cl₂ gas to form an absorber film pattern 4a (FIG. 3(c)).

Subsequently, the resist pattern 11a was removed by ashing or with a resist stripping solution. Finally, wet cleaning was performed with pure water (DIW) to fabricate the reflective mask 200 (FIG. 3(d)). Furthermore, the mask can be inspected for defects as necessary following wet cleaning followed by suitably correcting any mask defects.

In the reflective mask 200 of the present example, the pattern was able to be confirmed to be able to be drawn as designed even if the resist pattern 11 on the NiTa film was drawn with an electron beam. In addition, since the NiTa film is an amorphous alloy, processability in chlorine-based gas is favorable and the absorber film pattern 4a was able to be formed with high accuracy. In addition, since the film thickness of the absorber pattern 4a is 39.8 nm, the thickness of absorber pattern 4a was able to be reduced more than absorber films formed with a conventional Ta-based material, thereby making it possible to reduce shadowing effects. In addition, when the second main surface (back surface) of the substrate 1 of the fabricated reflective mask 200 was irradiated with a laser beam from an Nd-YAG laser having a wavelength of 532 nm, positioning error of the reflective mask 200 was able to be corrected since the back surface conductive film 5 was formed with a Pt film having high transmittance.

The reflective mask 200 fabricated in the present example was placed in a EUV scanner followed by exposing the wafer, in which the processed film and resist film were formed on the semiconductor substrate, to EUV light. By then developing this exposed resist film, a resist pattern was formed on the semiconductor substrate having the processed film formed thereon.

A semiconductor device having desired properties was able to be manufactured by transferring this resist pattern to a processed film by etching and then going through various steps such as formation of an insulating film and conductive film, introduction of dopant and annealing.

### Example 2

Example 2 is the same as Example 1 with the exception of making the film thickness of 10 nm of the Pt film of the back surface conductive film 5 and providing the intermediate layer 6 composed of a Si₃N₄ film between the substrate 1 and Pt film.

Namely, the intermediate layer composed of a Si₃N₄ film was deposited at a thickness of 90 nm on the second main surface (back surface) of the SiO₂-TiO₂-based glass substrate 1 by reactive sputtering (RF sputtering) using a Si target in a mixed gas atmosphere of Ar gas and N₂ gas. Next, the back surface conductive film 5 composed of a Pt film was deposited at a film thickness of 10 nm by DC magnetron sputtering using a Pt target in an Ar gas atmosphere to fabricate a substrate with conductive film.

The second main surface (back surface) of the fabricated substrate with conductive film was irradiated with light of a wavelength of 532 nm, and measurement of transmittance yielded a value of 21%. In addition, measurement of sheet resistance according to the four terminal method yielded a value of 25 Ω/□.

The reflective mask blank 100 was fabricated for the substrate with conductive film obtained by laminating a Si₃N₄ film and Pt film using the same method as Example 1. As a result of measuring the degree of flatness of the back surface of the reflective mask blank 100 with a flatness measuring apparatus using optical interference, the back surface was confirmed to be a convex shape and have a degree of flatness of 95 nm.

Furthermore, when the degree of flatness of the back surface of the reflective mask blank was measured in the case of not providing the intermediate layer 6 composed of a Si₃N₄ film and using the back surface conductive film 5 composed of a Pt film having a film thickness of 10 nm, the back surface was able to be confirmed to be a convex shape and have a degree of flatness of 401 nm, and the Si₃N₄ film had a stress adjustment function.

Subsequently, the reflective mask 200 was fabricated. When the second main surface (back surface) of the substrate 1 of the fabricated reflective mask 200 was irradiated with the laser beam of a Nd-YAG laser having a wavelength of 532 nm, positioning error of the reflective mask 200 was able to be corrected since the intermediate layer 6 and the back surface conductive film 5 were formed with a Si₃N₄ film and Pt film having high transmittance.

### Example 3

Example 3 is the same as Example 2 with the exception of using a TaBO film for the intermediate layer 6 and changing the film thickness of the back surface conductive film 5 to 5 nm.

Namely, the intermediate layer 6 composed of a TaBO film was deposited at a thickness of 50 nm on the second main surface (back surface) of the SiO₂-TiO₂-based glass substrate 1 by reactive sputtering using a TaB mixed sintered target in a mixed gas atmosphere of Ar gas and O₂ gas. Next, the back surface conductive film 5 composed of a Pt film was deposited at a film thickness of 5 nm by DC magnetron sputtering using a Pt target in an Ar gas atmosphere to fabricate a substrate with conductive film.

The composition of the TaBO film was such that Ta:B:O=40.7:6.3:53.0. In addition, measurement of transmittance by irradiating the second surface (back surface) of the fabricated substrate with conductive film with light of a wavelength of 532 nm yielded a value of 22%.

The reflective mask blank 100 was fabricated for the substrate with conductive film obtained by laminating a TaBO film and Pt film using the same method as Example 1. As a result of measuring the degree of flatness of the back surface of the reflective mask blank 100 with a flatness measuring apparatus using optical interference, the back surface was confirmed to be a convex shape and have a degree of flatness of 220 nm.

Subsequently, the reflective mask 200 was fabricated. When the second main surface (back surface) of the substrate 1 of the fabricated reflective mask 200 was irradiated with the laser beam of a Nd-YAG laser having a wavelength of 532 nm, positioning error of the reflective mask 200 was able to be corrected since the intermediate layer 6 and the back surface conductive film 5 were formed with a TaBO film and Pt film having high transmittance.

### Comparative Example 1

In Comparative Example 1, a reflective mask blank and reflective mask were fabricated using the same method and structures as Example 1 and a semiconductor device was manufactured using the same method as Example 1 with the exception of using a single-layer TaBN film for the absorber film 4 and using CrN for the back surface conductive film 5.

The back surface conductive film 5 composed of a CrN film was formed on the second main surface (back surface) of the SiO₂-TiO₂-based glass substrate 1 by magnetron sputtering (reactive sputtering) under the conditions indicated below.

Back surface conductive film formation conditions: Cr target, mixed gas atmosphere of Ar and N2 (Ar: 90%, N: 10%), film thickness of 20 nm.

The single-layer TaBN film was formed instead of a NiTa film on the protective film 3 of the mask blank structure of Example 1. The TaBN film was deposited at a film thickness of 62 nm by reactive sputtering using a TaB mixed sintered target in a mixed gas atmosphere of Ar gas and N₂ gas.

The element ratio of the TaBN film was 75 at % of Ta, 12 at % of B and 13 at % of N. The refractive index n of the TaBN film at a wavelength of 13.5 nm was approximately 0.949 and the extinction coefficient k thereof was approximately 0.030.

Reflectance of the absorber film composed of the aforementioned single-layer TaBN film at a wavelength of 13.5 nm was 1.4%. In addition, measurement of transmittance by irradiating the second main surface (back surface) of the fabricated substrate with conductive film with light of a wavelength of 532 nm yielded a value of 5.8%.

Subsequently, a resist film was formed on the absorber film composed of the TaBN film using the same method as Example 1 and a desired pattern was drawn (exposed) thereon followed by developing and rinsing to form a resist pattern. Using this resist pattern as a mask, dry etching of the absorber film composed of the TaBN film was carried out using chlorine gas to form an absorber film pattern. Removal of the resist pattern, mask cleaning and the like were then carried out using the same method as Example 1 to fabricate a reflective mask.

The film thickness of the absorber pattern was 62 nm and shadowing effects were unable to be reduced. In addition, since transmittance of the back surface conductive film 5 was low, when the second main surface (back surface) of the substrate 1 of the fabricated reflective mask was irradiated with the laser beam of a Nd-YAG laser having a wavelength of 532 nm, positioning error of the reflective mask was unable to be corrected.

### BRIEF DESCRIPTION OF THE REFERENCE SYMBOLS

1 Substrate

2 Multilayer reflective film

3 Protective film

4 Absorber film

4a Absorber pattern

5 Back surface conductive film

6 Intermediate layer

11 Resist film

11a Resist pattern

50 Substrate with conductive film

100 Reflective mask blank

200 Reflective mask

1. A substrate with conductive film comprising:
a mask blank substrate used in lithography;
a conductive film formed on one of main surfaces of the mask blank substrate; and
an intermediate layer having a stress adjustment function i provided between the substrate and the conductive film,
wherein transmittance of a laminated film including the intermediate layer and the conductive film for light having a wavelength of 532 nm is not less than 20%.

2. The substrate with conductive film according to claim 1, wherein the intermediate layer is made of a material comprising at least one element selected from silicon (Si), tantalum (Ta) and chromium (Cr).

3. The substrate with conductive film according to claim 1, wherein the intermediate layer is made of a material comprising at least one substance selected from Si₃N₄, SiO₂, TaO, TaON, TaCON, TaBO, TaBON, TaBCON, CrO, CrON, CrCON, CrBO, CrBON and CrBCON.

4. The substrate with conductive film according to claim 1, wherein the film thickness of the intermediate layer is 1 nm to 200 nm.

5. The substrate with conductive film according to 4 claim 1, wherein the conductive film is made of a material comprising at least one element selected from platinum (Pt), gold (Au), aluminum (Al) and copper (Cu).

6. A substrate with multilayer reflective film comprising:
a substrate with conductive film comprising
a mask blank substrate used in lithography,
a conductive film formed on one of main surfaces of the mask blank substrate, and
an intermediate layer having a stress adjustment function provided between the substrate and the conductive film, transmittance of a laminated film including the intermediate layer and the conductive film for light having a wavelength of 532 nm being not less than 20%; and
a multilayer reflective film formed on the main surface on the opposite side from the side on which the conductive film of the substrate with conductive film being formed, wherein multilayer reflective film is obtained by alternately laminating a high refractive index layer and a low refractive index layer.

7. The substrate with multilayer reflective film according to claim 6, wherein a protective film is formed on the multilayer reflective film.

8. A reflective mask blank comprising:
a substrate with conductive film comprising
a mask blank substrate used in lithography,
a conductive film formed on one of main surfaces of the mask blank substrate, and
an intermediate layer having a stress adjustment function provided between the substrate and the conductive film, transmittance of a laminated film including the intermediate layer and the conductive film for light having a wavelength of 532 nm being not less than 20%;
a multilayer reflective film formed on the main surface on the opposite side from the side on which the conductive film of the substrate with conductive film being formed, multilayer reflective film being obtained by alternately laminating a high refractive index layer and a low refractive index layer; and
an absorber film formed on the multilayer reflective film.

9. A reflective mask comprising:
a substrate with conductive film comprising
a mask blank substrate used in lithography,
a conductive film formed on one of main surfaces of the mask blank substrate, and
an intermediate layer having a stress adjustment function provided between the substrate and the conductive film, transmittance of a laminated film including the intermediate layer and the conductive film for light having a wavelength of 532 nm being not less than 20%;
a multilayer reflective film formed on the main surface on the opposite side from the side on which the conductive film of the substrate with conductive film being formed, multilayer reflective film being obtained by alternately laminating a high refractive index layer and a low refractive index layer; and
an absorber pattern in which the absorber film is patterned, formed on the multilayer reflective film.

10. A method for manufacturing a semiconductor device comprising:
placing a reflective mask in an exposure apparatus having an exposure light source that emits EUV light, and
transferring a transfer pattern to a resist film formed on a transferred substrate, wherein
the reflective mask comprises:
a substrate with conductive film comprising
a mask blank substrate used in lithography,
a conductive film formed on one of main surfaces of the mask blank substrate, and
an intermediate layer having a stress adjustment function provided between the substrate and the conductive film, transmittance of a laminated film including the intermediate layer and the conductive film for light having a wavelength of 532 nm being not less than 20%;
a multilayer reflective film formed on the main surface on the opposite side from the side on which the conductive film of the substrate with conductive film being formed, multilayer reflective film being obtained by alternately laminating a high refractive index layer and a low refractive index layer; and
an absorber pattern, in which the absorber film is patterned, formed on the multilayer reflective film.

11. The substrate with multilayer reflective film according to claim 6, wherein the intermediate layer is made of a material comprising at least one element selected from silicon (Si), tantalum (Ta) and chromium (Cr).

12. The substrate with multilayer reflective film according to claim 6, wherein the intermediate layer is made of a material comprising at least one substance selected from Si₃N₄, SiO₂, TaO, TaON, TaCON, TaBO, TaBON, TaBCON, CrO, CrON, CrCON, CrBO, CrBON and CrBCON.

13. The substrate with multilayer reflective film according to claim 7, wherein the intermediate layer is made of a material comprising at least one element selected from silicon (Si), tantalum (Ta) and chromium (Cr).

14. The substrate with multilayer reflective film according to claim 7, wherein the intermediate layer is made of a material comprising at least one substance selected from Si₃N₄, SiO₂, TaO, TaON, TaCON, TaBO, TaBON, TaBCON, CrO, CrON, CrCON, CrBO, CrBON and CrBCON.

15. The reflective mask blank according to claim 8, wherein the intermediate layer is made of a material comprising at least one element selected from silicon (Si), tantalum (Ta) and chromium (Cr).

16. The reflective mask blank according to claim 8, wherein the intermediate layer is made of a material comprising at least one substance selected from Si₃N₄, SiO₂, TaO, TaON, TaCON, TaBO, TaBON, TaBCON, CrO, CrON, CrCON, CrBO, CrBON and CrBCON.

17. The reflective mask according to claim 9, wherein the intermediate layer is made of a material comprising at least one element selected from silicon (Si), tantalum (Ta) and chromium (Cr).

18. The reflective mask according to claim 9, wherein the intermediate layer is made of a material comprising at least one substance selected from Si₃N₄, SiO₂, TaO, TaON, TaCON, TaBO, TaBON, TaBCON, CrO, CrON, CrCON, CrBO, CrBON and CrBCON.

19. The method for manufacturing a semiconductor device according to claim 10, wherein the intermediate layer is made of a material comprising at least one element selected from silicon (Si), tantalum (Ta) and chromium (Cr).

20. The method for manufacturing a semiconductor device according to claim 10, wherein the intermediate layer is made of a material comprising at least one substance selected from Si₃N₄, SiO₂, TaO, TaON, TaCON, TaBO, TaBON, TaBCON, CrO, CrON, CrCON, CrBO, CrBON and CrBCON.
